(19) United States
(12) Patent Application Publication
(10) Pub. No.: US 2005/0145411 A1
(43) Pub. Date: Jul. 7, 2005

(54) Material for the production of functional elements comprising at least one foamable area and use of said functional elements for positioning and mounting objects

(76) Inventors: Ulf Feistel, Laasdorf (DE); Roland Diener, Weida (DE); Uwe Weinzierl, Jena (DE)

Correspondence Address: JORDAN AND HAMBURG LLP, 122 EAST 42ND STREET, SUITE 4000, NEW YORK, NY, 10168, US

(21) Appl. No.: 10/497,757

(22) PCT Filed: Jan. 23, 2003
(86) PCT No.: PCT/DE03/00197

(30) Foreign Application Priority Data
Jan. 24, 2002 (DE) 102034559

(51) Int. Cl. H05K 1/00

(52) U.S. Cl. 174/250

(57) ABSTRACT

The aim of the invention is to provide positioning and mounting options with improved handling characteristics even at places that are difficult to access or in other difficult conditions. Said aim is achieved by using functional elements comprising at least one area that can be foamed by supply energy. At least one of said areas is used as a positioning element for positioning an object or for stiffening flexible or easily bendable materials in a shape-stabilizing manner.

In many technical fields it is necessary to bring very different objects, such as for instance optical and electrical conductors, into certain positions in a simple manner, and in some cases to assemble them conforming to a shape or in some other manner in locations that are difficult to access or under other difficult conditions.

There is such a requirement for instance with flexible film conductors, which are increasingly displacing traditional printed circuit boards and copper conductors. Film conductors are distinguished by their low weight and volume, their flexibility, and by their mechanical and thermal load capacity, and they can contain a plurality of printed conductors that are separated from one another and that run parallel in one direction in a flat tape structure for connecting electrical points of contact.

Since the cable trees primarily used in vehicles in the past lead to ever increasing space and weight issues due to a constantly increasing number of electrical consumers, a transition to film conductor technology is underway in this regard as well in terms of power transfer. It has already been recognized that this can achieve up to a 40% reduction in weight, and up to a 70% reduction in space required as well as in the number of connecting elements is even possible.

In vehicles, known is including film conductors that are to be disposed in the dashboard in the injection molding process and subsequently injected them with a suitable foam or embedding them in such a foam. However, if the film conductors are laid from the front area of the vehicle to the rear area of the vehicle, which generally must be done via the roof or floor region, there are difficulties in handling and assembly due to the easily bendable material structure of the conductor films. The result is increased time expended.

Nor are these difficulties avoided when the printed circuit boards are applied to one side of a flexible film in accordance with DE 199 39 014 A1 and the other side of the film is connected to the surface of a component already present in the vehicle.

In addition, in signal and data transmission, conventional copper lines are increasingly being replaced by alternatives. The employment of plastic beam waveguides has a positive effect for instance on increasing EMC security, for which reason this optical transmission technology is finding increasingly broad areas of application.

In addition to assembly tasks, there are positioning tasks, such as for instance with polymer optical fibers when they are provided for transmitting light, in that for assuring the transmission function it is necessary to orient the fibers relative to other optical components.

The object of the invention is to create positioning and assembly options with improved handling properties, even in locations that are difficult to access or under other difficult conditions.

This object is achieved using functional elements with at least one area that can be foamed by adding energy in that at least one of the areas is used as an adjusting element for positioning an object or for stiffening an element.

The adjusting elements are produced using a location-selective and time-controlled addition of energy, in particular radiant energy, to at least one of the foamable areas, whereby an adjacent object is displaced due to a change in volume.

The stability-enhancing properties of areas that are foamed by means of the addition of energy and subsequently are hardened are utilized for shape-stabilizing stiffening of flexible and/or easily bendable materials and in particular for assembly elements.

One inventive material for producing functional elements with at least one foamable area comprises a thermoplastic matrix, foaming agents contained therein, and radiation-absorbing intercalates that are concentrated in one area, in which radiation absorption of NIR radiation for foaming is distributed uniformly across the entire thickness of the material.

The concentrations of the radiation-absorbing intercalates are advantageously 0.005 mass % to 0.1 mass % and the material thicknesses are 0.5 mm to 5 mm.

What is achieved due to the very low concentration of radiation-absorbing intercalates is that not only does absorption of the radiant energy occur in one near-surface layer of the thermoplastic matrix, but penetrates deep enough that the entire thickness of the plastic matrix is included.

The radiation-absorbing intercalates have two effects. First, the plastic matrix is heated. Above the glass transition temperature in the case of amorphous plastics, or above the crystallite melting point in the case of semi-crystalline plastics, for instance, the strength and viscosity of these materials drop sharply; they convert to a thermoplastic deformable state. In this state the materials are easily deformable by external or internal forces. For instance, plastics in this state can be foamed by gases that are released in their interior.

The second effect is the heating of the foaming agent beyond a specific temperature for each of these agents. Above this temperature these agents deteriorate very rapidly, releasing gases. These gases being released then generate the forces that lead to foam formation in the heated thermoplastic deformable plastic matrix and to its expansion.

Similar dyes or pigments or a mixture of different dyes or pigments or a mixture of dyes and pigments that have been matched in terms of their absorption behavior to the wavelength range of the radiation to be used for foaming are suitable for the radiation-absorbing intercalates for converting radiant energy that is introduced in a location-selective manner. What is important is that in the pre-determined volume element of the area to be foamed there is the most uniform possible absorption of the radiant energy in order to assure uniform conversion to heat, which is itself a requirement for homogenous formation of foam. In addition, the radiant energy should be almost completely converted to heat.

Advantageously, the radiation-absorbing intercalates come from the range of inorganic blue, brown, or black pigments. Examples of this are ultramarine blue (Na₈[Al₆Si₆O₂₄])S₂₋₄ᵣ, iron oxide brown (Fe₂O₃), iron oxide black (Fe₃O₄), indium tin oxide, graphite, or carbon black. Phtalocyanine pigments, for instance, are suitable as organic pigments for this. Dyes that can be used come from derivatives of perylene carboxylic acid or even soluble phtalocyanines. In addition, conjugated polymers that have high absorption in the NIR range can be employed in their oxidized or reduced form. Among these are e.g. polyaniline or poly (3,4 ethylene dioxythiophene).

The thermoplastic matrix material can comprise thermoplastics that permit uniform distribution of the components contained therein, such as e.g. ABS, PC, PMMA, and bulk plastics such as LD-PE, HD-PE, PP, PS, and EVA (use of abbreviations in accordance with ISO 1043-1).

In the invention, preferred foaming agents are chemical foaming agents that are very stable under ambient conditions and that emit large quantities of gas very rapidly at elevated temperatures while deteriorating. The starting temperature for the release of gas that is required for foaming is matched to the properties of the matrix material. In particular the deterioration temperature of the foaming agent is specified with regard to the softening temperature of the matrix material. That is, the foaming agent should not release the majority of gas until at a temperature that permits thermoplastic deformation of the matrix material.

The foaming agent and the matrix material are combined using the normal procedures for the plastics-processing industry.

Foaming agents to be used can come from the groups of hydrogen carbonates (NaHCO₃), ammonium salts (NH₄)HCO₃, (NH₄)₂CO₃, (NH₄)NH₂CO₂), urea derivatives, diazo compounds (azodicarbamide), semicarbazides (para toluene sulfonyl semicarbazide), tetrazoles (5-phenyl tetrazole), or other heterocycles that have a high nitrogen content (N,N′-dinitroso pentamethylene tetramine).

Preferably 2 mass % to 20 mass % foaming agent is added to the plastic matrix for producing materials that foam well.

Finally, additional additives, supplements, and modifiers can be contained in the material for producing the functional elements provided these do not impede the described energy conversion and the foaming of the thermoplastic matrix material. Among these are for instance additional coloring agents that do not impede the absorption of the laser radiation, antioxidants, UV stabilizers, heat stabilizers, antistatic agents, and softeners. Furthermore, additives that promote the formation of the foam can also be contained, such as e.g. nucleating agents and foam stabilizers.

Preferably lasers are employed for preparing the radiant energy for the foaming, since these in particular assure location-selective introduction of the radiant energy into a pre-determined volume element. Particularly preferred are diode lasers, since they are particularly suitable due to their beam profile for introducing the light energy uniformly across the entire cross-section of the volume element to be foamed. The diode lasers provided for use emit primarily in the near-infrared (NIR) wavelength range of approx. 0.8 μm-2.5 μm.

The object is also achieved by a method for positioning an object with a positioning device, comprising a carrier that contains foamable material in at least one area with which the object to be positioned is in physical contact and in which the positioning of the object by location-selective foaming of the material occurs through volume expansion.

Advantageously, the foaming occurs by means of radiant energy in the near infrared that is introduced in a time-controlled location-selective manner, as can be provided by lasers, in particular diode lasers.

The subject of the invention is furthermore a positioning device comprising a carrier that contains foamable material in at least one area that acts as adjusting means for an object to be positioned by location-selective and time-controlled foaming.

The positioning device can have a hollow cylinder for a carrier, the enclosed hollow space of which receives the object to be positioned, and the sheath of which contains at least one adjusting means made of foamable material oriented toward the center of the hollow cylinder.

The object to be positioned can be placed on the foamable material.

Intersecting printed conductors, for instance, can be brought into contact with one another in that the printed conductors, as object to be positioned, are placed on two carriers that face one another with intersecting printed conductors so that location-selective foaming of the foamable material produces a contact in at least one of the pairs of intersecting conductors.

In accordance with the invention, the object is furthermore achieved by a molded assembly element produced from a flexible tape material that is provided with a shape-stabilizing stiffener made of a material that foams when energy is added and then hardens.

The existing handling and assembly problem is thus eliminated by converting an otherwise flexible element into a molded and consolidated structure using a foamable and hardenable material. In the case of a tape material, if the issue is a conductor structure with at least one flexible printed conductor, using the invention obtains in a simple manner a finished assembly component with the required curves and bends that can be handled with no problems in the assembly process, such as for instance when attached in roof rails in an automobile. Electrically conductive films provided for the printed conductors can be applied to a carrier material.

It is particularly advantageous that the tape material retains its previous flexible properties even after the foamable material has been applied and can be worked and processed in numerous ways as long as the foaming and hardening processes are not performed. Thus, electrically conductive films can always be molded, stamped, or structured like films, regardless of whether or not the foamable material has already been applied.

In addition to using the invention in flexible film conductors for conducting electrical current, in another advantageous embodiment molded structures of glass fiber conductors can also be produced for transmitting light and/or information.

The aforesaid object is furthermore inventively achieved by a method for producing a molded assembly component made of flexible tape material in which applied to the flexible tape material is a foamable material that, after the tape material is molded, can be foamed, for instance by means of adding energy, which can be produced e.g. by laser radiation, and subsequently is hardened to a stiffener that stabilizes the shape.

For shaping the tape material, a tool mold that conforms to the assembly location should be used in which the tape material can be advantageously received using suction.

The invention is described in greater detail in the following using examples and drawings.

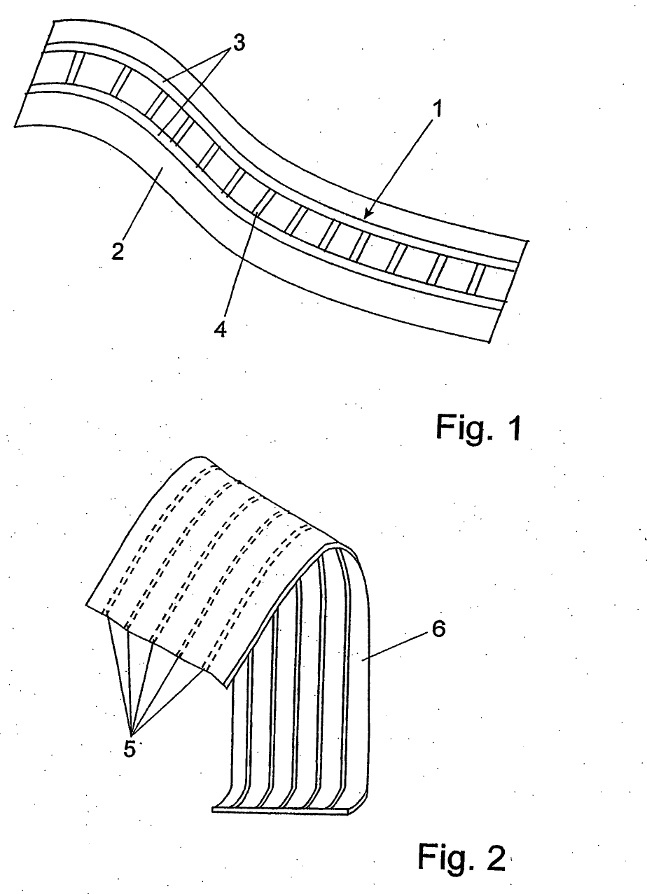

FIG. 1 is a segment from a tool mold with a molded flexible printed conductor;

FIG. 2 is a moldable carrier material with applied printed conductors;

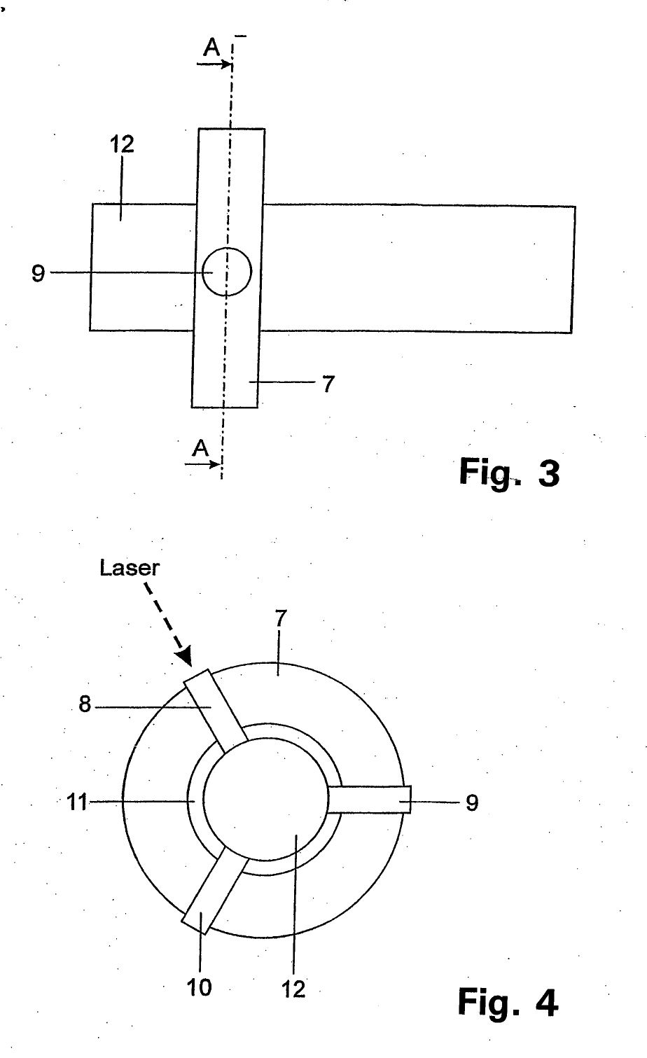

FIG. 3 is a side elevation of a positioning device for e.g. polymer optical fibers (POF);

FIG. 4 is a section A-A through the positioning device in accordance with FIG. 3;

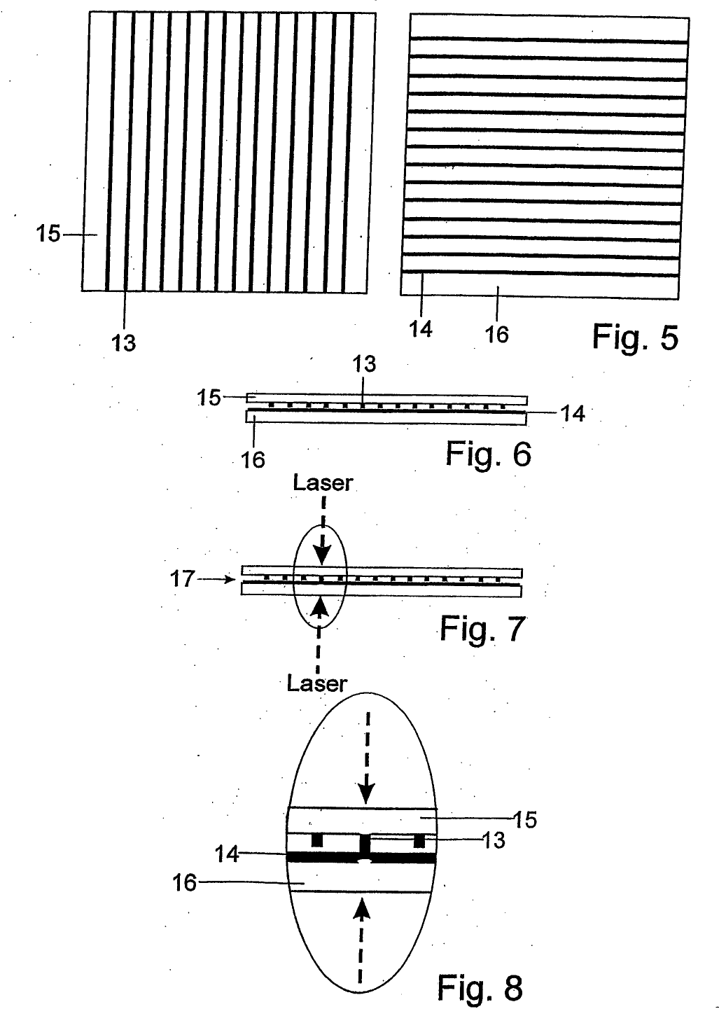

FIG. 5 illustrates two carriers with applied printed conductors;

FIG. 6 illustrates the arrangement of the two carriers in which intersecting printed conductors oppose one another for producing contacts by foaming selected areas;

FIG. 7 is the arrangement in accordance with FIG. 6 in which the two printed conductors contact one another;

FIG. 8 is an enlarged segment of the contacting printed conductors.

Inventive materials and pre-formed parts or semi-finished products that are location-selectively foamed in a subsequent process can be produced using various methods:
Sintering of initial powder substances in heated tools
Processing from a liquid phase (solution/suspension) by spraying, brushing, rubbing, raking, or pressing
Compounding by extrusion

For the sintering process, which essentially occurs using the method of hot stamping of plastic parts, the initial materials are used in powder form. It is advantageous to use grain size fractions that have similar grain sizes in order to prevent segregation/sedimentation among the different grain sizes. Uniform distribution of the coloring agents, which should be used in very small quantities, can be assured e.g. by applying powder or using powder color master batches. These powder mixtures are added to heatable tools that contain the contour of the desired semi-finished product/pre-formed part as a cavity for molding. The powders are sintered together at an elevated temperature. The increase in temperature is a function of the matrix plastic employed. For amorphous plastics, temperatures employed are preferably between the glass transition temperature and a temperature that is 40 K above the glass transition temperature. For semi-crystalline plastics, sintering temperatures slightly below the crystallite melting point, in particular temperatures of ±10 K of the Vicat B temperature (DIN ISO 306) are preferred. Applying pressure preferably in the range of 50 bar to 300 bar causes the material to flow into the mold while mixing. Placing the cavity under a vacuum can improve the mold-filling process and the density of the sintering body.

Processing out of the liquid phase (varnish production and processing) requires the production of a liquid that can be applied. This can be either a solution or a suspension. The requirement for applicability is that all of the components necessary for the foamable material, that is, the thermoplastic matrix material, the foaming agent, and the radiation-absorbing intercalates are contained. For producing a suspension, dispersion agents or emulsifiers for stabilization can also be contained.

The material components are dissolved in the appropriate portions in an organic solvent or an organic solvent mixture or are suspended in a solvent/water mixture. The viscosity of the liquids and the evaporative and wetting behaviors are adjusted such that the liquid can be applied using varnish processing technologies that are known per se.

After applying the liquid e.g. by brushing, spraying, raking, dipping, or pressing, and after physical drying, the applied layer of foamable material can be stored or further processed.

In the extrusion of components for continuous semi-finished products, the components are mixed with one another in the desired ratios and melted, mixed/homogenized, and subsequently molded. Care should be taken that the processing temperature and the materials to be used, that is, the matrix material and the foaming agent, are matched to one another such that the matrix material can be melted and homogenized but the temperature required for this does not lead to a situation in which the foaming agent deteriorates while releasing gas.

### EXAMPLE 1

20 kg EVA granulate are mixed with 1513 g azodicarbamide and 108 g of a 2% carbon black master batch in a drum mixer station. The resulting mixture contains the individual components in portions of 92.99%, 7%, and 0.01% (relative to the carbon black portion).

The mixture is melted and homogenized in an extruder using the processing parameters provided by the plastics manufacturer for the plastic granulate. The material is molded into a 2-mm thick plate using a flat sheet die.

This plate is subjected to defined laser radiation. A fiber-coupled diode laser with a wavelength of 808 nm and a maximum output of 30 W is used for this. The laser radiation is focussed on the contour to be foamed using an optical head. The laser is moved over the component at a constant speed using a motion system (portal). The laser system in this case is equipped with a pyrometer that measures the temperature on the surface of the material to be processed and regulates the laser output corresponding to a pre-specified temperature.

The material can be foamed along the motion contour at a temperature of 180° C. and a motion speed of 10 mm/s.

### EXAMPLE 2

20 kg LD-PE granulate are mixed with 1081 g azodicarbamide and 540 g of a 2% graphite master batch in a drum mixer station. The resulting mixture contains the individual components in portions of 94.95%, 5%, and 0.05% (relative to the graphite portion).

The mixture is melted and homogenized in an extruder using the processing parameters provided by the plastics manufacturer for the plastic granulate. The material is molded into a 0.5-mm thick film using a flat sheet die.

This film is subjected to defined laser radiation. A general unshielded diode laser with a wavelength of 940 nm and a maximum output of 25 W is used for this. The geometry of the general unshielded laser (beam of 20 mm×1.5 mm) is duplicated as a foamed area on the film at a laser exposure time of 0.4 s and a laser output of 20 W.

### EXAMPLE 3

85 g of a PP powder (sieve fraction 125 μm-250 μm) are intimately mixed with 15 g pounded azodicarbamide and 0.1 g finely powdered ITO (indium tin oxide). The resulting mixture contains the individual components in portions of 84.9%, 15%, and 0.1%. The mixture is then sintered into a 2-mm thick plate in a compression mold at 150° C. and 200 bar.

When treating this plate with a general unshielded diode laser with a wavelength of 940 nm (2 s, 20W), the contour of the general unshielded laser is duplicated on the plate as a foamed area.

### EXAMPLE 4

10 g 5-phenyltetrazol are ground with 0.1 g vanadyl phthalocyanine in a ball mill, taking care that the temperature does not rise above 80° C. 90 g PMMA powder are added to and mixed with the powder thus obtained. The resulting mixture contains the individual components in portions of 89.9%, 10%, and 0.1%. The mixture is then sintered into a 2-mm thick plate in a compression mold at 130° C. and 200 bar.

A foamed structure can be produced on the component when this plate is treated with a laser-coupled 808-nm diode laser system (focus diameter 0.8 mm, 40 W, 5 mm/s).

### EXAMPLE 5

90 g PC, 10 g N,N′-dinitroso pentamethylene tetramine, and 0.005 g Uvinol (BASF product name) are dissolved in a solvent mixture comprising 100 mL 2-propoxyethanol and 900 mL 1.3 dioxolane while heating slightly (T<40° C.) and stirring constantly. The solids portion of the solution contains the individual components in portions of 89.995%, 10%, and 0.005%.

The varnish is applied to a substrate made of polymide film by raking in a wet film thickness of 200 μm. Laser treatment takes place after the varnish has dried. A fiber-coupled diode laser with a wavelength of 808 nm is used. Location-selective foaming occurs at a processing speed of 5 mm/s and an output of 30 W.

The products, which are pre-formed parts or semi-finished products, can be embodied, processed, and employed as functional elements in various ways due to the foamable areas.

In the segment of the tool mold illustrated in FIG. 1, a flexible printed conductor 1 lies on a bearing surface 2 that corresponds to the installation path for the printed conductor 1. In the present embodiment, the printed conductor 1 comprises a stamped aluminum or copper film conductor in which thin strips 3 are separated from one another by spacers 4. The shape of the printed conductor 1, which is created by the bearing surface, is preferably achieved using a suctioning process, for which purpose suitable suction sites (not visible in the figure) are provided in the bearing surface 2.

Another embodiment can provide for bringing the printed conductor 1 into the intended shape by pressing it onto the bearing surface 2.

Regardless of how the bearing surface that is used for molding the printed conductor 1 is produced in the tool mold, the aluminum or copper film conductors used are provided on one side with a foamable material, e.g. by surface brushing, compression, or spraying, that can be foamed by adding energy, preferably by using laser radiation, so that once this material has hardened a rigid structure that conforms to the profile of the tool mold results from the original flexible printed conductor 1.

In accordance with FIG. 2, the film conductors 5 can be applied to a thin carrier 6 which of course must be flexible enough that it can be caused to conform to the contour of the tool mold using suction or pressing.

The inventively molded structure is not limited solely to electrical film conductors. Glass fiber conductors or other flexible (easily bendable) tape material can be embodied as a molded structure, such as a finished assembly component, in a suitably designed tool mold.

The positioning device illustrated in FIGS. 3 and 4 illustrates another application for functional elements with foamable areas.

A carrier embodied as a hollow cylinder 7 contains in its sheath a plurality of adjusting means, in the present exemplary embodiment three adjusting means 8, 9, 10, that are oriented toward the center of the hollow cylinder 7 and that are made of foamable material. The enclosed hollow space 11 receives an object to be positioned such as e.g. a polymer optical fiber 12. In addition to their use in communications engineering, where they are used in local networks for data exchange similar to glass fibers, polymer optical fibers are also employed in lighting systems, in particular for illuminating hazardous locations or for decentral illumination, such as e.g. in an automobile.

This entails the need to position the fibers that transmit the light in relation to other optical components (e.g., light source, lenses, diffusors).

The positioning device in accordance with FIGS. 3 and 4 can be used for this purpose in that the radiant energy of a laser is coupled into the adjusting means 8, 9, and 10. Depending on the desired position of the fiber 12, a required energy quantity acts upon one or more of the adjusting means 8, 9, and 10. Foaming is caused depending on the energy quantity employed, which results in a corresponding increase in volume of the adjusting means 8, 9, and 10 and radial displacement of the fiber 12 in the desired direction.

The laser radiation used for the foaming does not result in any negative impact on the polymer optical fiber 12, since fibers provided for light transmission do not absorb in the near infrared used.

Of course the application of the positioning device is not limited exclusively to positioning of optical fibers. The positioning device can be adapted appropriately to other objects to be positioned, as well. What is essential is the creation of adjusting elements by irradiation of foamable areas for different lengths of time, and that the change in volume of the adjusting elements can cause the displacement of an adjacent object.

The position of objects is also changed in another application of the functional elements provided with foamable areas. In this case this concerns printed conductors 13 and 14 that are applied to foamable material of the carriers 15 and 16, in accordance with FIGS. 5 through 8.

The carriers 15 and 16 can in particular be films or thin plates that are made of laser-foamable materials and that are provided with printed conductors. Known technologies can be used for applying the printed conductors, as long as required heat treatment does not lead to initiation of the foaming process.

Suitable are e.g. hot stamping, such as is also used in 3-D MID processes (3-D MID—3 dimensional molded interconnected devices). In addition, laminating and structuring of copper films analogous to printed circuit board engineering is also possible.

Corresponding to FIG. 6, the two carriers 15 and 16 are positioned with the printed conductors 13 and 14 facing and intersecting one another and spaced from one another at a distance that is less than the thickness by which the two carriers 15 and 16 can be foamed in the direction of one another using a laser treatment.

A contact is then produced in a pair of intersecting conductors by location-selective foaming of the two carriers 15 and 16 with a suitable laser (FIGS. 7 and 8) in that the gap 17 is closed by the material expansion that is caused.

1. A material for producing functional elements having at least one foamable area, said material comprising:
a thermoplastic matrix;
foaming agents, said foaming agents being contained within said matrix;
radiation-absorbing intercalates, said intercalates being concentrated in an area of said material; and
said material having a thickness, said material being adapted for absorbing NIR radiation so that said foamable area foams, said foam being distributed uniformly across said entire thickness of said material.

2. The material of claim 1, wherein said radiation-absorbing intercalates are inorganic blue, brown, or black pigments.

3. The material of claim 2, wherein said radiation-absorbing intercalates are ultramarine blue (Na₈[Al₆Si₆O₂₄])S₂₋₄, iron oxide brown (Fe₂O₃), iron oxide black (Fe₃O₄), indium tin oxide, graphite, or carbon black.

4. The material of claim 1, wherein said radiation-absorbing intercalates comprise organic pigments.

5. The material of claim 4, wherein said organic pigments comprise phtalocyanine pigments.

6. The material of claim 1, wherein said radiation-absorbing intercalates comprise dyes.

7. The material of claim 6, wherein said dye derivatives comprise perylene carboxylic acids.

8. The material of claim 6, wherein said dyes comprise soluble phtalocyanines.

9. The material of claim 1, wherein said radiation-absorbing intercalates comprise conjugated polymers having high absorption in the NIR range, said polymers being in an oxidized or a reduced form.

10. The material of claim 9, wherein said conjugated polymers comprise polyaniline or poly (3,4-ethylene dioxythiophene).

11. The material of claim 10, wherein said material has a thicknesses of 0.5 mm to 5 mm.

12. The material of claim 11, wherein said radiation-absorbing intercalates have a mass % of 0.005 mass % to 0.1 mass %.

13. The material of claim 12, wherein said foaming agents in said thermoplastic plastic matrix have a mass % of 2 mass % to 20 mass %.

14. The material of claim 13, further comprising at least one of additional additives, supplements and modifiers.

15. A sinter material, said material being formed by plastic hot stamping, said sinter material comprising the material of claim 1.

16. A liquid or varnish, said liquid or varnish comprising a solution or suspension, said liquid or varnish comprising the material of claim 1.

17. A method of displacing an object comprising:
obtaining functional elements, said elements having at least one foamable area for positioning said object; and
applying energy to at least one of said foamable areas, said energy application being location-selective and time-controlled, so that a volume of said foam changes and the object is displaced.

18. The method of claim 17, wherein said elements comprise at least one foamable area, said area being adapted for stiffening a flexible or bendable material.

19. The method of claim 18 further comprising:
applying energy to an area of said elements so that said area foams and then hardens so that said foamable elements form a shape-stabilizing stiffener.

20. The method of any one of claims 17 through 19, wherein the energy is laser radiation, the radiation being near infrared.

21. A method for positioning an object with a positioning device, said positioning device comprising a carrier, said carrier containing foamable material in at least one area, said method comprising:
contacting said object to be positioned with said positioning device; and
expanding said foamable material, said expanding being location-selective, so that said object is positioned.

22. The method of claim 21, further comprising introducing radiant energy to said material, said radiant energy being introduced in a time-controlled location-selective manner, so that said foamable material foams.

23. The method of claim 22, further comprising applying lasers for introducing said radiant energy.

24. The method of claim 23, wherein said lasers comprise diode lasers, said lasers irradiating a wavelength, said wavelength being NIR.

25. A positioning device comprising a carrier, said carrier containing, in at least one area, a foamable material, said foamable material being adapted for adjusting the position of an object, said foamable material being adapted for location-selective time-controlled foaming.

26. The positioning device of claim 25, wherein said carrier is a hollow cylinder having an enclosed hollow space, said enclosed hollow space being adapted for receiving the object, said cylinder containing at least one adjusting means, said adjusting means comprising foamable material, said adjusting means being oriented toward the center of said hollow cylinder.

27. The positioning device of claim 25, wherein said object is placed against said foamable material.

28. The positioning device of claim 27, comprising two carriers, said two carriers having printed conductors, said conductors defining said object, said carriers facing one another so that said printed conductors intersect, wherein said location-selective foaming of said foamable material produces a contact between the intersecting conductors.

29. A molded assembly element, said element being formed by:
obtaining a flexible tape material, said material having a shape-stabilizing stiffener, said stiffener comprising a material, said material being adapted for receiving energy so that said material foams and then hardens; and
irradiating said flexible tape material.

30. The molded assembly element of claim 29, wherein said tape material includes a conductor structure, said structure having at least one flexible printed conductor.

31. The molded assembly element of claim 30, wherein said flexible printed conductor comprises an electrically conductive film.

32. A molded assembly element of claim 30, wherein said flexible printed conductor is a glass fiber conductor for transmitting at least one of light and information.

33. A method for producing a molded assembly element, said element comprising flexible tape material, said method comprising:
applying a foamable material to said flexible tape material;
molding said tape material; and,
adding energy to said foamable material so that said foamable material foams and then hardens to a shape-stabilizing stiffener.

34. The method of claim 33, further comprising obtaining a tool mold and molding said tape material.

35. The method of claim 34, further comprising applying laser radiation for adding energy.

36. The method of claim 35, further comprising applying suction so that said tool mold receives said tape material.

37. The method of claim 36, wherein said tape material includes a conductor structure with at least one flexible printed conductor.

38. The method of claim 36, wherein said flexible printed conductor is an electrically conductive film conductor.

39. The method of claim 36, wherein said flexible printed conductor is a glass fiber conductor adapted for transmitting one or more of light and information.
